(19) United States
(12) Patent Application Publication
(10) Pub. No.: US 2007/0247254 A1
(43) Pub. Date: Oct. 25, 2007

(54) Modulation of an RF Transmit Signal

(75) Inventor: Douglas Todd Hayden, Boise, ID (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Preco Electronics, Inc., Boise, ID (US)

(21) Appl. No.: 11/624,112

(22) Filed: Jan. 17, 2007

Related U.S. Application Data
(63) Continuation-in-part of application No. 11/278,936, filed on Apr. 6, 2006.

(51) Int. Cl. H03C 3/00

(52) U.S. Cl. 332/117

(57) ABSTRACT

Techniques for reducing interference among transceivers are disclosed. A transistor generates a radio frequency transmit signal in response to a generated pulse. The pulse is generated when transitions are detected in a clock signal. The clock signal is produced by an oscillator block which includes a ceramic resonator configured as a clock source. When interference is detected, the pulse applied to the transistor is varied. The frequency of the transmit signal is optionally modulated by varying the temperature of a resonator element. To vary this temperature, the current flowing through one or more resistive elements positioned in proximity of the resonator element is varied according to a control signal. As the level of this current flow varies, the amount of heat emitted by the resistive elements varies, thereby changing the temperature of the resonator element which has a relatively high temperature sensitivity.

### CROSS-REFERENCE TO RELATED APPLICATIONS

This application claims the benefit of and is a continuation-in-part of U.S. application Ser. No. 11/278,936 filed on Apr. 6, 2006, which is incorporated by reference in its entirety for all purposes.

### BACKGROUND OF THE INVENTION

The present invention relates to electronic circuits, and more particularly, to modulating the frequency of an RF signal being transmitted

In high-frequency electronic circuits, there is often a need to change the frequency of the transmit signal, i.e., to shift from one frequency to another, in order to prevent interference to and from other RF transceiver units. Such frequency shifting may be achieved by varying the bias to a varactor diode, that in turn, changes the capacitance values disposed in a crystal oscillator circuit.

In other conventional systems, to change the oscillation frequency, a potentiometer is used to vary the resistance of an RC network coupled to the drain terminal of an RF transistor thereby to vary the drain bias voltage. Therefore, the oscillation frequency of the transmit signal can only be varied manually. A need continues to exist for a circuit operative to dynamically vary the oscillation frequency of an RF transmit signal.

### BRIEF SUMMARY OF THE INVENTION

In accordance with one embodiment of the present invention, a transistor generates a radio frequency transmit signal in response to a generated pulse. The pulse is generated when transitions are detected in a clock signal. The clock signal is produced by an oscillator block which includes a ceramic resonator configured as a clock source. In some embodiments, the ceramic resonator exhibits a wide initial frequency tolerance in relation to its specified operating frequency such that the probability of interference between units of a multiple transceiver system is minimized. In an exemplary embodiment, the ceramic resonator has an initial frequency tolerance of at least ±1000 parts per million (0.1%). The ceramic resonator may also have a temperature sensitivity such that the frequency of the clock signal varies based upon an ambient temperature of the ceramic resonator. In various embodiments, the temperature sensitivity of the ceramic resonator is at least ±1000 parts per million (0.1%). The ceramic resonator also exhibits a stable phase noise characteristic that is appropriate for use with a successively sampled system.

In accordance with another embodiment of the present invention, a control block is adapted to dynamically adjust a control signal. The control signal is delivered to the oscillator block and causes a current to flow through one or more resistive elements. The resistive elements produce heat in response to the current flow and the heat changes an ambient temperature of the ceramic resonator. Because of its relatively high temperature sensitivity, the ceramic resonator responds to the change in temperature by producing a variation in the frequency of the clock signal, ultimately changing the frequency of the transmit signal. The control block may adjust the amount of heat produced by the one or more resistive elements by varying the duty cycle of the control signal according to a pseudo-random value. In some embodiments, the clock signal is delivered to a synchronous receiver to provide phase coherent detection of the generated transmit signal. In an exemplary embodiment, the frequency of the clock signal and the transmit signal are changed when interference is detected at the synchronous receiver.

### BRIEF DESCRIPTION OF THE DRAWINGS

FIG. 1 is a schematic diagram of a circuit configured to modulate the frequency of a transmit signal, in accordance with one embodiment of the present invention.

FIG. 2 is a schematic diagram of a circuit configured to modulate the frequency of a transmit signal, in accordance with another embodiment of the present invention.

FIG. 3 is a timing diagram of a number of signals generated by the circuit shown in FIG. 1, in accordance with one exemplary embodiment of the present invention.

FIG. 4 is a schematic diagram of a circuit configured to modulate the frequency of a transmit signal, in accordance with another embodiment of the present invention.

FIG. 5 is a schematic diagram of a circuit configured to modulate the frequency of a transmit signal, in accordance with another embodiment of the present invention.

FIG. 6 is a schematic diagram of a circuit configured to modulate the frequency of a transmit signal, in accordance with another embodiment of the present invention.

FIG. 7 is a functional block diagram of a frequency modulation circuit according to an embodiment of the present invention.

### DETAILED DESCRIPTION OF THE INVENTION

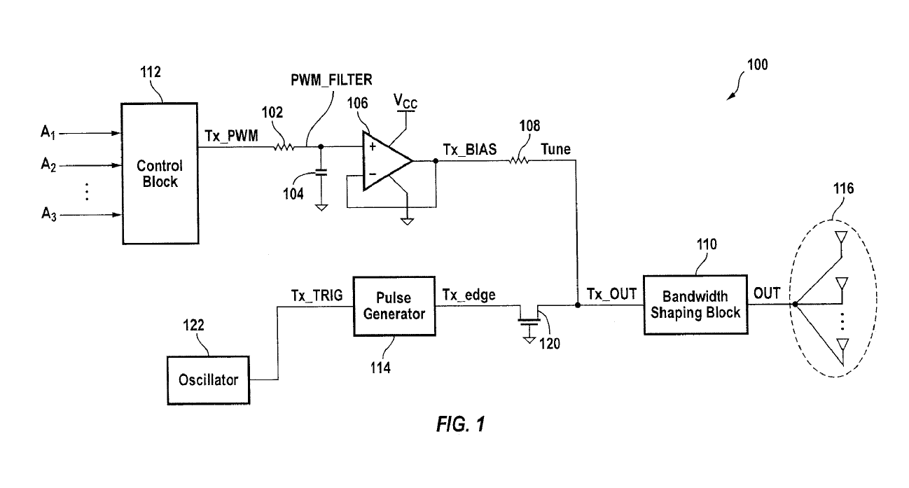

FIG. 1 is a schematic diagram of a radio frequency (RF) transmitter circuit 100 configured to generate and vary the frequency of signal OUT transmitted by one or more transmit antennas 116, in accordance with one embodiment of the present invention. Circuit 100 is shown as including a control block 112, a resistor 102, a capacitor 104, an amplifier 106, a resistor 108, a bandwidth shaping circuit 1 10, a pulse generator 114, an oscillator block 122 and an RF transistor 120. Circuit 100 is adapted to generate an RF signal OUT having a frequency that may be dynamically varied, in part, using the control signals A₁, A₂ . . . and Aₙ, applied to control block 112 in accordance with one embodiment of the present invention.

Control block 112 includes a pulse width modulator (not shown) adapted to generate a pulse-width modulated (PWM) signal TX_PWM that is a control signal and is applied to the first terminal of resistor 102. In one embodiment, control block 112 further includes a register that can be accessed for read/write operations and whose value is used to vary the duty cycle of signal TX_PWM generated by the pulse-width modulator. The register value may be initially set during production so as to ensure that the frequency of signal OUT is within the required limits. In one embodiment, this register value may be stored in a non-volatile memory, such as an electrically erasable programmable read only memory (EEPROM) also disposed in control block 112. In accordance with the present invention, when changes in the frequency of the transmit signal OUT are required to inhibit, for example, interference to or from other RF signals, the register value is varied to cause the duty cycle of signal TX_PWM to change. Thus, in accordance with the present invention, by varying the frequency of signal OUT using the duty cycle of signal TX_PWM via the register disposed in control block 112, interference to or from other sources of RF is inhibited.

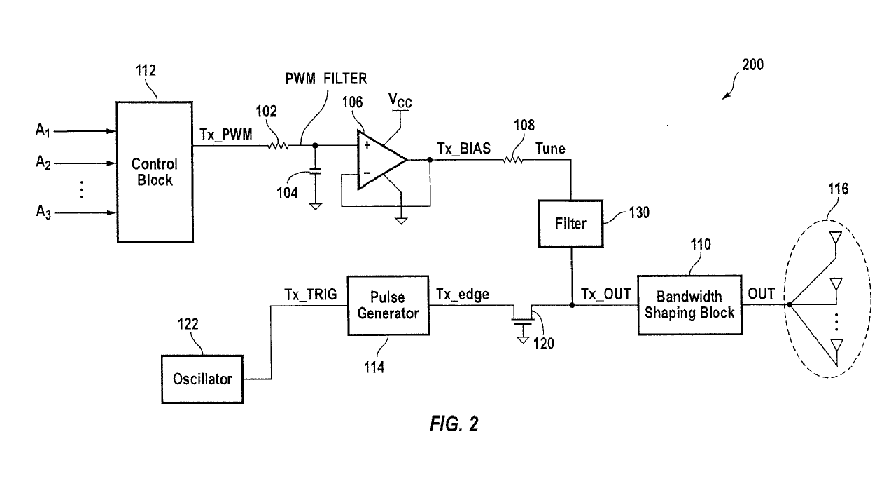

Resistor 102 and capacitor 104 form a low pass filter that filters out the high frequency components of signals from TX_PWM and delivers the filtered out signal PWM_Filter to the positive input terminal of operational amplifier 106. Operational amplifier 106 is configured as a voltage follower having an output terminal that is coupled to its negative input terminal, and a positive input terminal that receives signal PWM_Filter. Signal TX_Bias generated by op amp 106 has a higher current drive capability than signal PWM_Filter and is applied to a first terminal of resistor 108. The other terminal of resistor 108 generates signal Tune that is applied to the drain terminal of RF transistor 120. In some embodiments, such as that shown in FIG. 2, a filtering block 130, which may be an RC filter, is used to filter out the high frequency components of signal Tune and apply the filtered signal to the drain terminal of transistor 120.

Bandwidth shaping block 110 is adapted to shape the bandwidth of signal TX_Out generated at the drain terminal of transistor 120 so as to satisfy the transmit spectrum requirements established by the FCC or other regulating body. In one exemplary embodiment, transistor 120 operates at a repetition rate of 2 MHz, and signal Tune has a frequency that is several orders of magnitude smaller than 2 MHz. In one embodiment, signal Tune varies between 3.25 volts to 4.75 volts when a supply of 5 volts is used.

Oscillator block 122 is adapted to generate a signal TX_Trig applied to an input terminal of pulse generator 114. Pulse generator 114 generates a pulse signal TX_Edge upon detecting a transition on signal TX_Trig generated by oscillator block 122. In one embodiment, signal TX_Trig is a square-wave signal. Pulse signal TX_Edge generated by pulse generator 114 is applied to the source terminal of transistor 120.

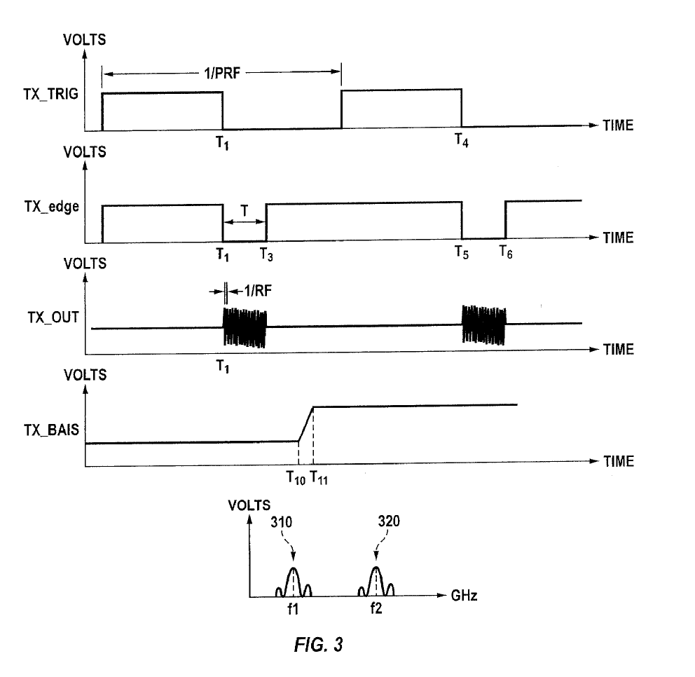

FIG. 3 is a timing diagram of various signals generated by transmitter circuit 100, in accordance with some embodiments. Signal TX_Trig is shown as having a period of 1/PRF, where PRF refers to the Pulse Repetition Frequency. At time T1, signal TX_Trig is shown as making a high-to-low transition. Accordingly, pulse generator 114 generates a pulse signal TX Edge having a duration defined by times T2 and T3. At time T4, signal TX_Trig is shown as making a second high-to-low transition. Accordingly, pulse generator 114 generates a second pulse TX_Edge having a duration defined by times T5 and T6. Signal TX_Edge has relatively fast rise and fall times.

The length of the conductive line that couples the gate terminal of transistor 120 to the ground terminal is selected so as to achieve a certain capacitive, inductive, and conductive values. In other words, the length of this conductive gate is a factor affecting the oscillation frequency of transistor 120, in accordance with well known transmission line effects. When the high-to-low pulse transitions on signal TX_Edge are received by transistor 120, the drain terminal of transistor 120 starts to oscillate at a frequency defining the frequency of transmit signal OUT, based on the bias points of transistor 120 and the spectral energy contained in signal TX_Trig, as shown by signal TX_OUT. The oscillation is transient and dissipates after a time period. When signal TX_Edge returns to its previous value at, e.g., times T3, T6, the oscillation at the drain terminal of transistor 120 is terminated, as shown in FIG. 3. A pulse is caused to appear on signal TX_Edge at a rate that can vary, in some embodiments, from several microseconds to sub-nanoseconds. In one embodiment, control block 112is a standard off-the-shelf microcontroller, such as model number DSCPIC30F4012, available from Microchip Technology located in Chandler Ariz. USA.

Also shown in FIG. 3is a timing diagram of signal TX_Bias. Prior to time T10, signal TX_Bias is assumed to have been generated using a duty cycle of 20%, and after time T11 signal TX_Bias is assumed to have been generated using a duty cycle of 60%. Accordingly signal TX_Bias has a DC level that is smaller prior to time T10 than it is after time T11. The frequency spectrum of the transmit signal OUT is also shown in FIG. 3. When signal TX_Bias has a duty cycle of 20%, output signal OUT has a frequency spectrum identified with reference numeral 310. When signal TX_Bias has a duty cycle of 60%, output signal OUT has a frequency spectrum identified with reference numeral 320. As is seen from FIG. 3, by changing the duty cycle of signal TX_PWM and thereby changing the bias level of signal TX_Bias, the frequency of signal OUT is varied dynamically, in accordance with the present invention.

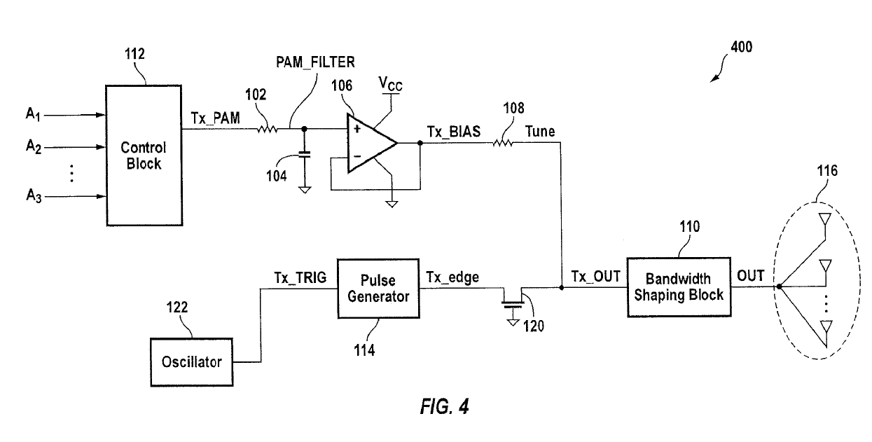

FIG. 4 is a schematic block diagram of a radio frequency (RF) transmitter circuit 400 configured to generate and vary the frequency of signal OUT transmitted by one or more transmit antennas 116, in accordance with another embodiment of the present invention. In transmitter circuit 400, control block 112 is configured to generate signal TX_PWM, whose amplitude is modulated using control signals A1, A2 . . . A3. In other words, signal TX_PWM is a pulse-amplitude modulated signal. The remaining blocks shown in FIG. 4 operate in the same manner shown and described above with respect to FIG. 1. By modulating the amplitude of signal TX_PWM, via varying, for example, one or more register values disposed in control block 112, the voltage applied to the drain terminal of transistor 120 via signal Tune is changed to thereby vary the frequency of signal OUT.

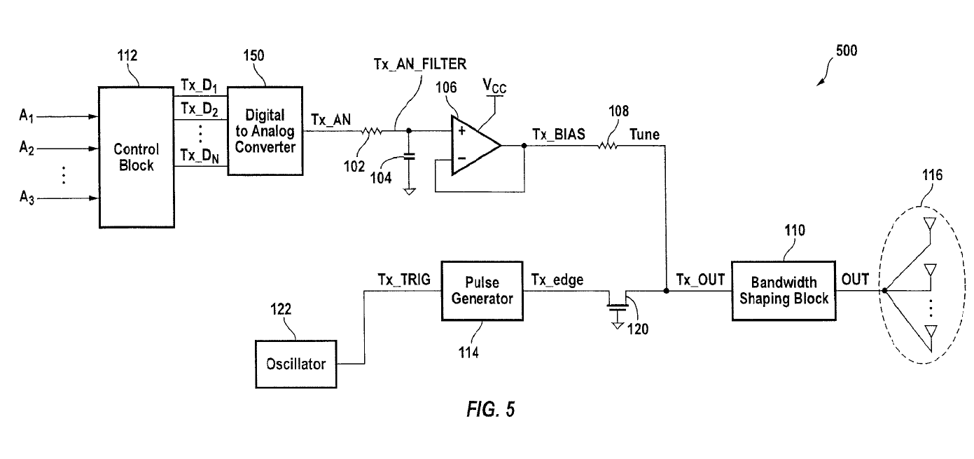

FIG. 5 is a schematic block diagram of a radio frequency (RF) transmitter circuit 500 configured to generate and vary the frequency of signal OUT transmitted by one or more transmit antennas 116, in accordance with another embodiment of the present invention. In transmitter circuit 500, control block 112 is configured to generate a multi-bit digital signal TX_D having N bits, namely signals TX_D₁ TX_D₂ . . . TX_D_{N} that are applied to digital-to-analog converter 150. Signal TX_D may be varied by changing the control signals A1, A2 . . . A3 applied to the input terminals of control block 112. As shown in FIG. 5, the N bits of signal D are applied to a digital-to-analog converter 150 that converts the received digital signal D to a corresponding analog signal TX_AN. Signal TX_AN is applied to resistor 102. The remaining blocks shown in FIG. 4 operate in the same manner shown and described above with respect to FIG. 1. By changing one or more bits of signal TX_D, the voltage applied to the drain terminal of transistor 120 via signal Tune is changed to thereby vary the frequency of signal OUT.

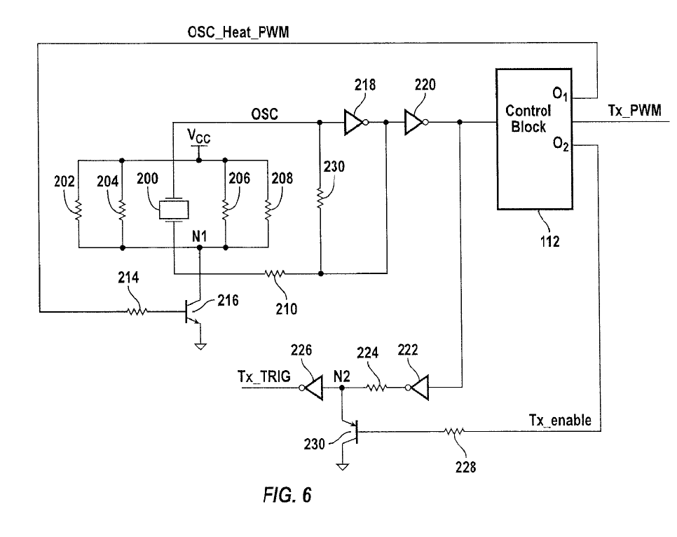

In accordance with another embodiment of the present invention, the frequency of signal OUT is varied by varying the frequency of signal TX_Trig (FIG. 1) using one or more heating elements placed in proximity of an oscillator that generates the clock signal used to generate signal TX_Trig. Referring to FIG. 6, a pair of resistors 202, 204 are shown as positioned adjacent and to the left of oscillator 200, and a pair of resistors 206, 208 are shown as positioned adjacent and to the right of oscillator 200. While, in FIG. 6, four resistors are showing as being placed in proximity of oscillator 200, in other embodiments, more or fewer than four resistors may be used in any physical configuration that allows heat transfer to the oscillator. The following description is provided with reference to a control signal that is pulse-width modulated. It is understood, however, that the present invention is applicable to any other control signal with characteristics that may be varied using any other known techniques, such as digital-to-analog conversion, pulse amplitude modulation, and the like.

One terminal of each of resistors 202, 204, 206, and 208 is coupled to the supply power Vcc. The other terminal of these resistors is coupled to the collector terminal of transistor 216 via node N 1. Control block 112, also shown in FIG. 1, generates signal OSC_Heat_PWM whose duty cycle may varied by changing the value of a register (not shown) disposed in control block 112.

Resistors 202, 204, 208, and 210 are used as heating elements heating oscillator 200 in order to vary its frequency. The base terminal of transistor 216 receives signal OSC_Heat_PWM whose duty cycle can be varied 0%, i.e., fully off, to 100%, i.e., fully on. By varying the duty cycle of signal OSC_Heat_PWM, the average on-time of transistor 216 is varied thus changing the average current that flows through resistors 202, 204, 206 and 208. In other words, by varying the duty cycle of signal OSC_Heat_PWM, the current through these four resistors and thus the amount of heat generated by these resistors may be modified. It is understood that oscillator 200 has a non-zero temperature coefficient and its oscillation frequency varies as a function of the temperature.

Signal OSC is generated by oscillator 200 in combination with a pair of inverters 218 and 220. The output of inverter 218 is applied to a terminal of oscillator 200 via resistor 210. The signal generated by inverter 220 is applied to an input terminal of inverter 222 whose output signal is applied to one of the terminals of resistor 224. The other terminal of resistor 224 is coupled to node N2 and to an input terminal of inverter 226. Signal TX_Trig, which is also shown in FIG. 1, is generated by inverter 226. Inverters 218, 220, in combination with resistors 230 and 210 form a start-up circuitry that is used to place oscillator 200 in the proper operating condition during a start-up mode. Inverter 218 in combination with resistors 224 and 210 and oscillator 200 form a clock circuit selected for optimum start-up performance and oscillator drive level. Inverter 220 is used to buffer the output from the clock circuit into other circuits such as control block 112 and inverter 222.

Output signal TX_Enable, also generated by control block 112, is applied to the base terminal of transistor 230 via resistor 228. The collector terminal of transistor 230 is coupled to the ground terminal and the emitter terminal of transistor 230 is coupled to node N2. Signal TX_Enable is used to switch transistor 230 on or off, thereby enabling or disabling signal TX_Trig.

To achieve frequency modulation by changing the temperature of the oscillator 200, periodically a synchronous receiver (not shown) is used to detect for any received signal within the synchronous receiver's bandwidth that may be causing interference. During such times, signal TX_Enable signal is disabled, i.e., the transmitter is disabled. Next, the receiver continues to look for interference from other RF signal generators. To inhibit such interference, signal OSC_Heat_PWM is varied to change the amount of heat generated by resistors 202, 204, 206, and 208, thereby to change the temperature of oscillator 200. Changing this temperature causes the frequency of signal TX_Trig to change, which provides a changing synchronous receiver clock and provides the same change to the energy spectrum stimulus to transistor 220 causing a RF transmission at a different frequency. The disabling of the transmitter is carried out periodically to detect for interference followed by additional heat applied to the oscillator. The changing application of heat to the oscillator continues until no interference is received by the synchronous receiver.

In one embodiment, control block 112 which may be a commercially available micro-controller detects interference from other RF sources. In some embodiments, oscillator 200 has a temperature sensitivity of at least ±1000 ppm over its operating temperature range. A shift of approximately 4 ppm in time-base may be sufficient to provide the desired rejection of interfering RF sources by the synchronous receiver. In accordance with the present invention, in some embodiments, a total shift in frequency of 100 ppm or more is achieved.

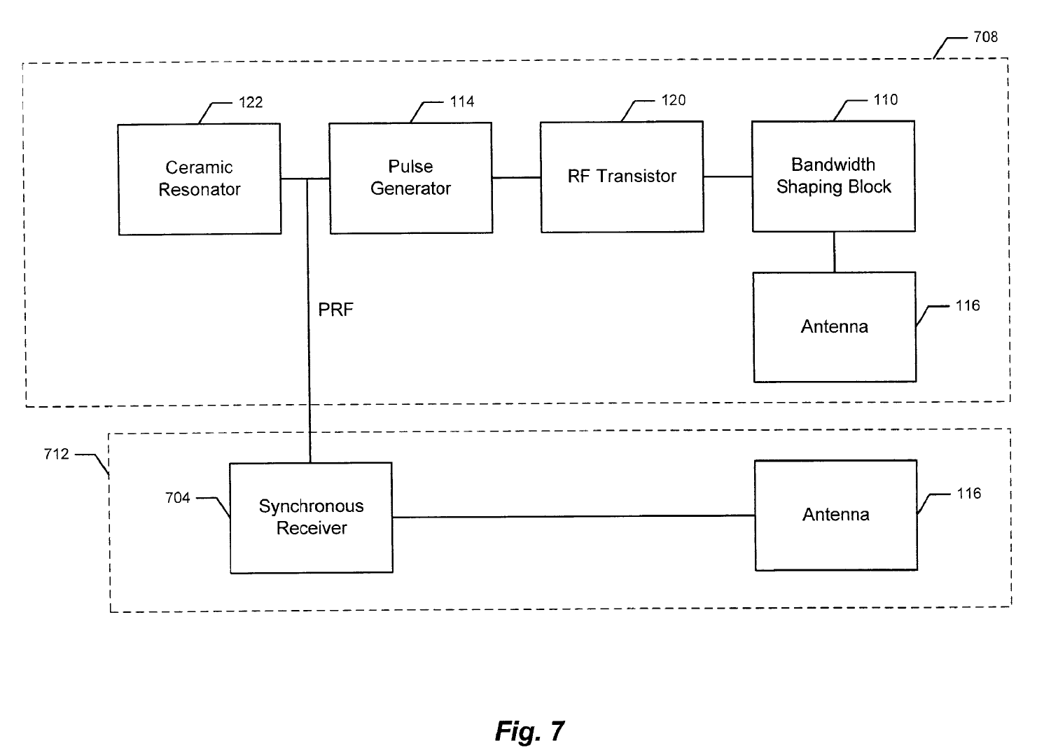

FIG. 7 shows an embodiment of the present invention such as might be used in a microwave impulse radar (MIR) system. Ceramic resonator block 122 is coupled with synchronous receiver block 704 and also with pulse generator block 114. Ceramic resonator block 122 supplies signal TX_Trig to pulse generator 114 as part of transmitter 708 as previously described. Synchronous receiver block 704 also receives signal TX_Trig, identified here by its pulse repetition frequency (PRF), as part of a discriminating receiver 71 2. As shown, separate antennas 116 are provided for transmitter 708 and receiver 712. However, it will be understood, that a common antenna structure or multiple antenna structures may also be used.

Ceramic resonator block 122 may be optimized in relation to the inventive frequency modulation techniques by proper clock source selection. Unlike conventional designs in which a clock source is selected to achieve precise control of oscillation frequency and to minimize changes due to temperature variation, the present invention uses variation in these characteristics to achieve a performance improvement. By selecting a clock source with a wide initial frequency tolerance and/or a relatively high temperature sensitivity, the probability of interference between multiple transceiver units is minimized. For instance, the probability that transmitter 708 will interfere with neighboring transceiver units (not shown) is significantly reduced when each transceiver unit includes a clock source with a wide frequency tolerance. In some embodiments, ceramic resonator block 122 replaces dynamic transistor biasing for reducing inter-unit interference.

Ceramic resonator block 122 includes a ceramic resonator 200. Ceramic resonator 200 may be selected to have a frequency tolerance of approximately ±1000 parts per million (ppm) or about 0.1% in relation to its specified operating frequency. In some embodiments, depending upon the particular application, ceramic resonator 200 may have a frequency tolerance of ±5000 ppm (0.5%) or more. Because a typical synchronous receiver has a discrimination bandwidth of about ±4 ppm, the chance of inter-unit interference using ceramic resonator 200 is very small. By comparison, a crystal clock source may have a frequency tolerance of ±50 ppm or less. Assuming a uniform distribution in frequency tolerance, the probability of inter-unit interference is reduced from approximately 1 in 1,200 using a crystal frequency source to about 1 in 2,000,000 using a ceramic resonator with a frequency tolerance of about ±5000 ppm.

Ceramic resonator 200 may also be chosen according to its temperature sensitivity characteristics. In some embodiments, ceramic resonator 200 has a temperature sensitivity of approximately ±1000 ppm (0.1%) over a typical 125° C. operating range. Depending upon the application, an increased temperature sensitivity of ±5000 ppm (0.5%) or more may be selected. For example, a temperature sensitivity of ±0.5% corresponds to an average sensitivity of 8 ppm/° C. As a result, ceramic resonator 200 requires a relatively small temperature change to produce a frequency, or PRF, shift that is outside the conversion range of synchronous receiver 704. Thus, if the bandwidth of synchronous receiver 704 is approximately ±4 ppm, an ambient temperature change of only 0.5° C. at ceramic resonator 200 may produce a shift in PRF sufficient to avoid interference from other units. Additional benefits of ceramic resonator elements include stable phase noise characteristics, small size, and low cost.

Referring again to FIG. 6, control block 112 may vary the duty cycle of signal OSC_Heat_PWM according to a pseudo-random number to further minimize the probability of inter-unit interference. In some embodiments, control block 112 includes a random number generator. When interference is detected, control block 112 may cause the random number generator to produce a new value and may store this new value in the register associated with signal OSC_Heat_PWM. The effect of this operation is to vary the duty cycle of OSC_Heat_PWM according to the pseudo-random value and to thereby vary the heat produced by resistors 202, 204, 208, and 210. Varying the heat produced causes the ambient temperature of ceramic resonator 200 to change. Due to its temperature sensitivity, ceramic resonator 200 responds to the change in temperature by producing a corresponding change in the clock signal. The change in clock signal varies the transmit signal and effectively avoids the source of interference.

A unique identifier may be provided as a seed value to the random number generator to greatly reduce the probability of continuing interference. For example, if two transceivers according to the present invention are interfering and each responds by changing the temperature of its ceramic resonator using a pseudo-random value that is based upon its unique identifier, the chance of continued interference is minimized. In some embodiments, a serial number of the transceiver unit may be used as the seed for the random number generator.

The above embodiments of the present invention are illustrative and not limiting. Various alternatives and equivalents are possible. In particular, the clock source of the ceramic resonator block may include non-ceramic clock source elements having temperature sensitivity, frequency tolerance, and/or phase noise properties similar to those described above. The invention is not limited by the technique used to dynamically vary the biasing voltage applied to the terminals of the high frequency transistor, which include modulation, e.g., pulse-width, pulse amplitude or otherwise, digital-to-analog conversions, and the like. The invention is not limited by the type of integrated circuit in which the present disclosure may be disposed. Nor is the disclosure limited to any specific type of process technology, e.g., CMOS, Bipolar, or BICMOS that may be used to manufacture the present disclosure. Other additions, subtractions or modifications are obvious in view of the present disclosure and are intended to fall within the scope of the appended claims.

What is claimed is:

1. A circuit operative to modulate the oscillation frequency of a transmit signal, the circuit comprising:
an oscillator block adapted to generate a clock signal, the oscillator block including a ceramic resonator configured as a clock source;
a pulse generator block adapted to generate a pulse signal in response to detecting a transition of the clock signal; and
a transistor having a first terminal configured to receive a biasing signal and a second terminal configured to receive said pulse signal,
wherein said transistor generates a radio frequency signal in response to a low-to-high or high-to-low transition of said pulse signal.

2. The circuit of claim 1 wherein said ceramic resonator has a temperature sensitivity characteristic and the frequency of said clock signal varies based on said temperature sensitivity characteristic.

3. The circuit of claim 2 wherein said temperature sensitivity of said ceramic resonator is at least ±1000 parts per million (0.1%) over an operating temperature range that includes an ambient temperature of said circuit.

4. The circuit of claim 1 wherein said ceramic resonator has a frequency tolerance of at least ±1000 parts per million (0.1%) in relation to its specified operating frequency.

5. The circuit of claim 1 wherein said ceramic resonator has a stable phase noise characteristic.

6. The circuit of claim 1 wherein said clock signal enables a phase coherent detection of said radio frequency signal by a synchronous receiver.

7. The circuit of claim 1 further comprising a control block adapted to generate a control signal, and wherein said control signal is delivered to said oscillator block.

8. The circuit of claim 7 wherein said oscillator block further comprises one or more resistive elements disposed in proximity to said ceramic resonator, and wherein a current flows through said one or more resistive elements in response to said control signal.

9. The circuit of claim 8 wherein said one or more resistive elements produce heat in response to said current flow and said heat changes an ambient temperature of said ceramic resonator.

10. The circuit of claim 9 wherein said ceramic resonator produces a variation in the frequency of said clock signal in response to said change of said ambient temperature.

11. The circuit of claim 9 wherein said control block varies a duty cycle of said control signal to thereby control said heat produced by said one or more resistive elements.

12. The circuit of claim 11 wherein said control block changes the duty cycle of said control signal in response to an indication that interference is detected at a synchronous receiver.

13. The circuit of claim 11 wherein the duty cycle of said control signal is based upon a value of a register disposed in said control block.

14. The circuit of claim 11 wherein said control block varies the duty cycle of said control signal according to a pseudo-random value.

15. The circuit of claim 7 wherein said control block is a commercially available microcontroller.

16. The circuit of claim 7 wherein said control block is configured to disable delivery of said clock signal to said pulse generator block.

17. The circuit of claim 16 wherein said clock signal is delivered to a synchronous receiver when delivery of said clock signal to said pulse generator block is disabled.

18. A method of varying a frequency of a clock signal, the method comprising:
modulating a control signal;
varying current flow through one or more resistive elements in response to the modulation of the control signal thereby to vary a heat generated by the one or more resistive elements; and
varying a temperature of a ceramic resonator in response to the variation in the generated heat, wherein variation in the temperature of the ceramic resonator produces a variation in the frequency of the clock signal.

19. The method of claim 18 wherein said ceramic resonator has a temperature sensitivity characteristic and the frequency of said clock signal varies based upon said temperature sensitivity characteristic.

20. The method of claim 19 wherein said temperature sensitivity of said ceramic resonator is at least ±1000 parts per million (0.1%) within its specified operating temperature range.

21. The method of claim 18 wherein said ceramic resonator has a frequency tolerance of at least ±1000 parts per million (0.1%) in relation to its specified operating frequency.

22. The method of claim 18 wherein said ceramic resonator has a stable phase noise characteristic.

23. The method of 18 wherein the current flow through the one or more resistive elements is varied via a transistor having a first terminal adapted to receive said control signal, a second terminal coupled to a common terminal of the one or more resistive elements, and a third terminal coupled to the ground.
